(19) United States
(12) Patent Application Publication
(10) Pub. No.: US 2026/0337750 A1
(43) Pub. Date: Oct. 29, 2026

(54) DEPOSITION MASK, METHOD OF MANUFACTURING THE DEPOSITION MASK, METHOD OF MANUFACTURING DISPLAY DEVICE AND ELECTRONIC DEVICE INCLUDING DISPLAY DEVICE

(71) Applicant: Samsung Display Co., LTD., Yongin-si (KR)

(72) Inventors: Sung Woon KIM, Yongin-si (KR); Ji Hye HAN, Yongin-si (KR)

(21) Appl. No.: 19/660,764

(22) Filed: Apr. 28, 2026

(30) Foreign Application Priority Data
Apr. 29, 2025 (KR) 10-2025-0056275

(51) Int. Cl. C23C 14/04; C23C 14/12; G03F 7/12; G03F 7/16; H10K 59/12; H10K 71/16

(52) U.S. Cl. CPC C23C 14/042; C23C 14/12; G03F 7/12; G03F 7/168; H10K 59/12; H10K 71/166

(57) ABSTRACT

A method of manufacturing a deposition mask includes sequentially forming a protection film and a mask film on surfaces of a mask body. The method includes forming, by etching the mask film, an upper mask pattern comprising preliminary holes on the first surface of the mask body and a lower mask film on the second surface of the mask body. The method includes forming an additional protection film on a side surface of the mask body, forming an opening passing through the mask body by etching the mask body from the second surface, and forming deposition holes connected to the opening from the preliminary holes by removing a portion of the protection film exposed by the opening.

This application claims priority to Korean Patent Application No. 10-2025-0056275, filed on Apr. 29, 2025, and all the benefits accruing therefrom under 35 U.S.C. §119, the content of which in its entirety is herein incorporated by reference.

### BACKGROUND

### 1. Field

Embodiments of the present disclosure relate to a deposition mask, a method of manufacturing the deposition mask, a method of manufacturing a display device using the deposition mask, and an electronic device including the display device. More particularly, embodiments of the present disclosure relate to a deposition mask including a deposition hole and an opening, a method of manufacturing the deposition mask, a method of manufacturing a display device using the deposition mask, and an electronic device including the display device.

### 2. Related Art

In a display device, such as an organic light emitting diode (OLED) display device and a liquid crystal display device (LCD), a display substrate including, for example, a thin film transistor (TFT) and various wiring is provided. A display structure including electrodes and a light emitting layer may be formed on the display substrate.

For example, the OLED display device may include a light emitting element including an organic light emitting layer. The organic light emitting layer may be patterned for each color or each pixel using a deposition mask. As a resolution of the OLED display device increases, a fine patterning process is performed on the deposition mask.

### SUMMARY

One task of the present invention is to provide a deposition mask having improved mechanical stability and deposition reliability.

One task of the present invention is to provide a method of manufacturing a deposition mask having improved mechanical stability and deposition reliability.

One task of the present invention is to provide a method of manufacturing a display device using the deposition mask.

A task of the present invention is to provide an electronic device including the display device.

In a method of manufacturing a deposition mask, a protection film and a mask film are sequentially formed on surfaces of a mask body, the surfaces including a first surface and a second surface opposite each. By etching the mask film, an upper mask pattern including preliminary holes on the first surface of the mask body, and a lower mask film on the second surface of the mask body are formed. An additional protection film on a side surface of the mask body is formed. By etching the mask body from the second surface, an opening passing through the mask body is formed. By removing a portion of the protection film exposed by the opening, deposition holes connected to the opening from the preliminary holes are formed.

In some embodiments, the protection film may include an oxide-based insulating material, and the mask film may include a nitride-based insulating material.

In some embodiments, the additional protection film may include the oxide-based insulating material.

In some embodiments, the additional protection film may be formed by a thermal oxidation process.

In some embodiments, portions of the additional protection film may be formed together on an upper surface and an outer side surface of the upper mask pattern, and a surface of the lower mask film. The portions of the additional protection film may include a first portion formed on the upper surface and the outer side surface of the upper mask pattern, a second portion formed on the surface of the lower mask film, and a third portion formed on the side surface of the mask body. The third portion may be combined with the protection film on the side surface of the mask body.

In some embodiments, in forming the opening, a preliminary opening may be formed by etching the second portion of the additional protection film stacked on the second surface of the mask body, the lower mask film, and the portion of the protection film formed on the second surface of the mask body. The opening may be formed by etching the mask body through the preliminary opening.

In some embodiments, the additional protection film may be removed when the deposition holes are formed.

In some embodiments, removing the additional protection film may partially expose the side surface of the mask body.

Forming the preliminary opening may form a lower mask pattern from the lower mask film. Forming the preliminary opening may form a lower protection film pattern between the lower mask pattern and the mask body from the protection film.

In some embodiments, the side surface of the mask body may include a first inclined surface adjacent to the first surface, and a second inclined surface adjacent to the second surface. The lower mask pattern and the lower protection film pattern may cover the second inclined surface.

In some embodiments, the additional protection film may be removed by treating the additional protection film with a buffered oxide etchant (BOE) solution.

In some embodiments, the mask body may include silicon, and etching the mask body through the preliminary opening may be performed by wet etching using an alkaline etchant.

In some embodiments, in forming the upper mask pattern and the lower mask film, a photoresist film may be formed on an upper surface of the mask film. An outer portion of the photoresist film may be removed. A photoresist pattern may be formed from a remaining portion of the photoresist film. Etching the mask film using the photoresist pattern as an etch mask, etching the mask film may separate into the mask film into the upper mask pattern and the lower mask film.

In some embodiments, etching the mask film may partially etch the protection film formed on the side surface of the mask body. The additional protection film may cover the protection film on the side surface of the mask body.

In a method of manufacturing a display device, a backplane structure including a base substrate, a transistor formed on the base substrate, and pixel electrodes electrically connected to the transistor is formed. The backplane structure is aligned over the deposition mask manufactured according to the method described herein such that the pixel electrodes correspond to each of the deposition holes of the deposition mask. Light emitting layers may be formed on the pixel electrodes by injecting a light emitting material from the opening of the deposition mask into the deposition holes to form. A counter electrode is formed on the light emitting layers.

An electronic device includes a display device manufactured according to the method described herein, a memory, and a processor for executing data contained in the memory to control operation of the display device.

The electronic device may include virtual reality or augmented reality glasses, a smartphone, a tablet PC, a laptop, a television, a desk monitor, smart glasses, a head-mounted display, a smart watch, or an automotive electronic device.

A deposition mask includes a mask body including mask areas, a dummy area between the mask areas, an outer area surrounding the mask areas and the dummy area, openings respectively overlapping the mask areas; an upper mask pattern formed on an upper surface of the mask body and including deposition holes connected to the openings respectively overlapping the mask areas; and a fence structure selectively covering a lower surface portion of the dummy area and a lower edge of the outer area of the mask body.

In some embodiments, the fence structure may include a lower protection film pattern including an oxide-based insulating material, and a lower mask pattern including a nitride-based insulating material. The lower protection film pattern and the lower mask pattern may be stacked sequentially from the lower surface of the mask body.

In some embodiments, the fence structure may include an inner fence structure formed on the lower surface portion of the dummy area of the mask body; and an edge fence structure formed on the lower edge of the outer area of the mask body and partially covering a side surface of the mask body.

In some embodiments, the side surface of the mask body may include a first inclined surface adjacent the upper surface of the mask body, and a second inclined surface adjacent the lower surface of the mask body. The edge fence structure may cover the second inclined surface, but not the first inclined surface.

### BRIEF DESCRIPTION OF THE DRAWINGS

FIG. 1 is a schematic plan view illustrating a deposition mask according to example embodiments.

FIG. 2 is a schematic cross-sectional view illustrating a deposition mask according to example embodiments.

FIGS. 3-12 are schematic cross-sectional views illustrating a method of manufacturing a deposition mask according to example embodiments.

FIGS. 13 and 14 are partially enlarged cross-sectional views illustrating a method of manufacturing a deposition mask according to an example embodiment.

FIG. 15 is a schematic cross-sectional view illustrating a deposition mask according to example embodiments.

FIGS. 16-20 are schematic cross-sectional views illustrating a method of manufacturing a deposition mask according to example embodiments.

FIGS. 21-25 are schematic drawings illustrating a method of manufacturing a display device according to example embodiments.

FIG. 26 is an exploded perspective view illustrating an electronic device according to example embodiments.

FIG. 27 is a block diagram of an electronic device according to an embodiment.

FIG. 28 illustrates schematic drawings of an electronic device according to example embodiments.

### DETAILED DESCRIPTION

Hereinafter, example embodiments of the present invention will be described in more detail with reference to the accompanying drawings. In this case, the same reference numerals will be used for the same elements in the drawings, and repeated descriptions of the same elements will be omitted for clarity. The embodiments disclosed in the accompanying drawings are illustrative, and it should be understood that all modifications, equivalents, and substitutions falling in the spirit and scope of the present invention are included therein.

The terms such as "on", "connected to", and "coupled to" used in the present specification include not only direct placement, connection, or coupling, but also indirect placement, connection, or coupling where other components may be interposed therebetween.

Terms such as "first", "second", "below", "lower", "above", "upper", "upper surface", and "lower surface" are used to distinguish between different components or positions, and are not intended to indicate absolute positions or orders.

The term “substantially,” as used herein, means approximately or actually. The term “substantially equal” means approximately or actually equal. The term “substantially the same” means approximately or actually the same. The term “substantially perpendicular” means approximately or actually perpendicular. The term “substantially parallel” means approximately or actually parallel.

The terminology used herein is for the purpose of describing particular embodiments only and is not intended to be limiting. As used herein, "a", "an," "the," and “at least one” do not denote a limitation of quantity, and are intended to include both the singular and plural, unless the context clearly indicates otherwise. For example, "an element" has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

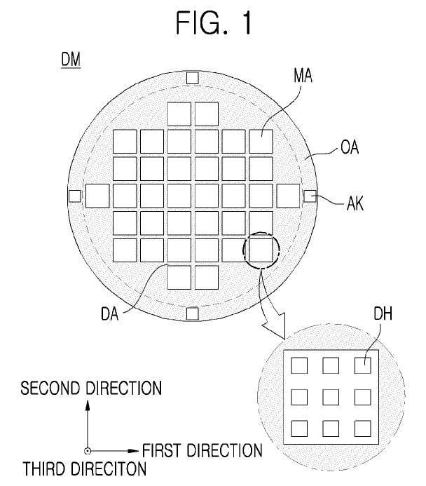

FIG. 1 is a schematic plan view illustrating a deposition mask according to example embodiments.

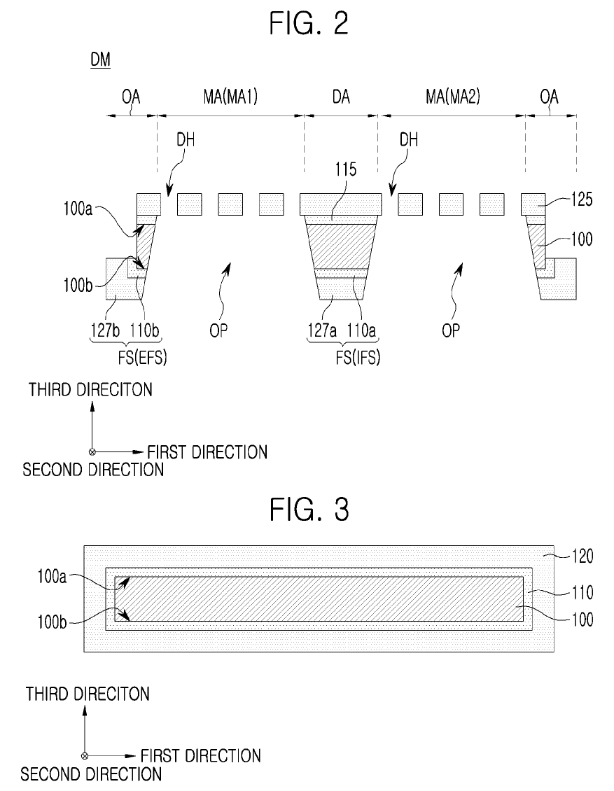

In FIG. 1, two directions perpendicular each other and parallel to a surface (upper surface or lower surface) of the deposition mask DM, or a surface (first surface 100a or second surface 100b) (refer to FIG. 2) of the mask body 100, are referred to as a first direction and a second direction. For example, the first direction may be a row direction of a display device and the second direction may be a column direction of the display device. A third direction may refer to a direction perpendicular to the first direction and the second direction. For example, the third direction may be a thickness direction of the deposition mask DM and the display device.

In the following drawings, the above definitions of direction may be applied substantially the same.

Referring to FIG. 1, the deposition mask DM may include a plurality of mask areas MA. In each mask area MA, deposition holes DH may be included. Through the deposition holes DH, a deposition source may be discharged onto a target substrate to form a target layer (for example, a light emitting layer).

For the sake of illustration, nine deposition holes DH are illustrated in each mask area MA, but the number of deposition holes DH may be increased without particular limitation.

In an embodiment, the mask area MA corresponds to each of the target substrate and may be provided as a patterned area for forming a pattern on each of the target substrate. For example, the plurality of mask areas MA may be used to perform a deposition process on a plurality of target substrates together. Accordingly, for example, process efficiency for forming the light emitting layer may be improved.

In an embodiment, the deposition process may be performed through the plurality of mask areas MA on a single target substrate.

The mask areas MA may be separated by a dummy area DA. The deposition mask DM may include an outer area OA. The outer area OA may surround the mask areas MA. The dummy area DA may include a residual area in the outer area OA excluding the mask areas MA.

In the outer area OA, an alignment key AK may be disposed. The alignment key AK may be used to align the deposition mask DM to correspond to a deposition location of the target substrate.

FIG. 2 is a schematic cross-sectional view illustrating a deposition mask according to example embodiments.

Referring to FIG. 2, as described herein, the deposition mask DM includes the plurality of mask areas MA in an outer area OA, and the mask areas MA may be separated by the dummy area DA. As illustrated in FIG. 2, a first mask area MA1 and a second mask area MA2 may be separated by the dummy area DA.

In the cross-sectional view of FIG. 2, two mask areas MA1, MA2 and one dummy area DA are illustrated in the outer area OA for ease of illustration, but three or more mask areas MA may be arranged separated by the dummy area DA.

The deposition mask DM may include a mask body 100 and a fence structure FS.

The mask body 100 may include a ceramic material or a metallic material. According to example embodiments, the mask body 100 may include a silicon (Si) substrate. The mask body 100 may be manufactured from a silicon wafer.

The mask body 100 may include a first surface 100a and a second surface 100b that are opposite each other. The first surface 100a and the second surface 100b may correspond to an upper surface and a lower surface of the mask body 100, respectively. The first surface 100a may be an outlet surface of a deposition source. The second surface 100bmay be a supply surface of the deposition source.

On the first surface 100a of the mask body 100, an upper mask pattern 125 including deposition holes DH may be disposed. The deposition holes DH may be formed in the mask areas MA1, MA2 portions of the upper mask pattern 125. The plurality of deposition holes DH may be formed in each of the first mask area MA1 and the second mask area MA2 that pass through the upper mask pattern 125.

The upper mask pattern 125 may include a nitride-based insulating material. According to example embodiments, the upper mask pattern 125 may include silicon nitride.

Between the upper mask pattern 125 and the first surface 100a of the mask body 100, an upper protection film pattern 115 may be disposed. The upper protection film pattern 115 may be included in the dummy area DA and the outer area OA, and may not be included in the mask area MA.

The upper protection film pattern 115 may include an oxide-based insulating material. According to example embodiments, the upper mask pattern 125 may include silicon oxide.

The mask body 100 may include an opening OP passing through the mask body 100. In example embodiments, one opening OP may be included for each mask area MA.

The opening OP may extend in the thickness direction of the mask body 100 and may be in common with, and integrally connected to, the deposition holes DH included in each mask area MA. In some embodiments, the width of the opening OP may gradually decrease in a direction from the second surface 100b toward the first surface 100a.

According to example embodiments, a fence structure FS may be formed on the second surface 100b of the mask body 100. The fence structure FS may include an inner fence structure IFS formed on the second surface 100b of the mask body 100 between neighboring mask areas MA and an edge fence structure EFS formed on a lower edge of the mask body 100.

The inner fence structure IFS may be included in the dummy area DA between neighboring mask areas MA. The inner fence structure IFS may include a first lower protection film pattern 110aand a first lower mask pattern 127a stacked sequentially from the second surface 100b of the mask body 100 in the dummy area DA.

The edge fence structure EFS may be formed on the second surface 100b of the mask body 100 in the outer area OA and on a portion of the side surface of the mask body 100. The edge fence structure EFS may partially cover the side surface of the mask body 100. The edge fence structure EFS may cover a lower side surface of the mask body 100.

The edge fence structure EFS may include a second surface 100b of the mask body 100 and a second lower protection film pattern 110b and a second lower mask pattern 127b stacked sequentially from the side surface.

The first and second lower protection film patterns 110a, 110b may include an oxide-based insulating material. According to example embodiments, the first and second lower protection film patterns 110a, 110b may include silicon oxide. The first and second lower protection film patterns 110a, 110b may include substantially the same material as the upper protection film pattern 115.

The first and second lower mask patterns 127a, 127b may include a nitride-based insulating material. According to example embodiments, the first and second lower mask patterns 127a, 127b may include silicon nitride. The first and second lower mask patterns 127a, 127b may include substantially the same material as the upper mask pattern 125.

The opening OP may pass through the fence structure FS and the mask body 100 together. The fence structure FS may surround a lower portion of the opening OP. According to example embodiments, the edge fence structure EFS and the inner fence structure IFS may be integrally connected in the dummy area DA adjacent to the outer area DA and form the fence structure FS, and a plurality of openings OP may pass through the fence structure.

According to the above-described embodiments of the present disclosure, the double-layered fence structure FS may protect the lower portion of the mask body 100. Accordingly, thermal damage to the mask body 100 may be prevented on the lower surface (second surface 100b) of the mask body 100 where a high temperature deposition source is introduced.

Further, the lower edge of the mask body 100 may be protected by the edge fence structure EFS. Accordingly, mechanical stress or impact to the lower edge of the mask body 100 that occurs during movement for alignment or loading of the deposition mask DM may be reduced.

FIGS. 3-12 are schematic cross-sectional views illustrating a method of manufacturing a deposition mask according to example embodiments.

In the descriptions of the method and processes herein, the operations may be performed in a different order than the order shown and/or described, or the operations may be performed in different orders or at different times. Certain operations may also be left out of the flowcharts, one or more operations may be repeated, or other operations may be added. Descriptions that an element “may be disposed,” “may be formed,” and the like include methods, processes, and techniques for disposing, forming, positioning, and modifying the element, and the like in accordance with example aspects described herein.

Referring to FIG. 3, the method may include forming a protection film 110 on a surface of the mask body 100. The method may include forming a mask film 120 on the protection film 110.

In some embodiments, the mask body 100 may include silicon. For example, the mask body 100 may be manufactured from a silicon wafer.

The protection film 110 may be continuously formed along the first surface 100a, the second surface 100b, and the side surfaces of the mask body 100. The protection film 110 may cover substantially the entire surface of the mask body 100.

The protection film 110 may be formed by a first oxidation process on the mask body 100. The first oxidation process may include thermal oxidation of the surface of the mask body 100. Accordingly, the protection film 110 may include a silicon oxide.

In some embodiments, the protection film 110 may be formed by depositing an oxide-based material. In an embodiment, the protection film 110 may be formed by depositing the silicon oxide by a chemical vapor deposition (CVD) process. For example, the protection film 110 may be formed by a low pressure chemical vapor deposition (LPCVD) process, a plasma chemical vapor deposition (PECVD) process, or the like.

A mask film 120 may be formed on the protection film 110. The mask film 120 may be formed to include a nitride-based insulating material, such as silicon nitride. The mask film 120 may be formed by a deposition process, such as a CVD process (for example, LPCVD process).

In some embodiments, the mask film 120 may be formed over the entire surface of the protection film 110. Accordingly, the mask film 120 may cover substantially the entire surface of the mask body 100.

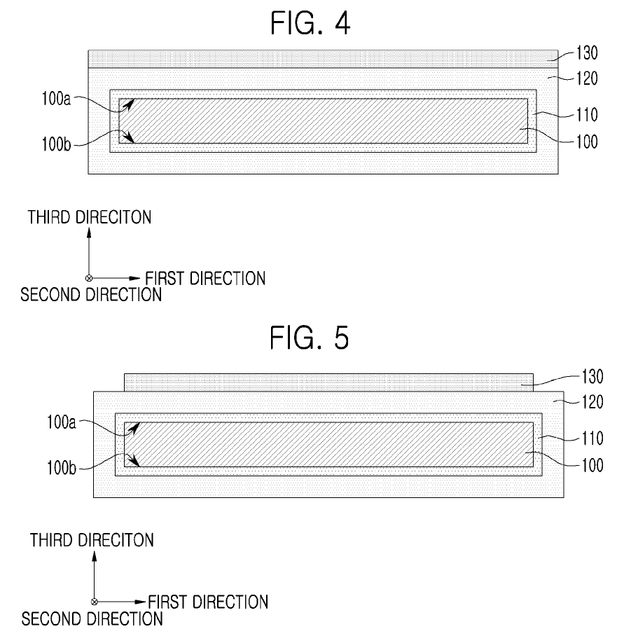

Referring to FIG. 4, the method may include forming a photoresist film 130 on an upper surface of the mask film 120.

According to example embodiments, a photoresist composition including a photosensitive resin may be applied to the upper surface of the mask film 120 by a coating process, such as a spin coating process. And then, the method may include curing the coated composition by a soft-baking process to form a photoresist film 130.

Referring to FIG. 5, the method may include removing an outer portion or edge portion of the photoresist film 130. According to example embodiments, the outer portion of the photoresist film 130 may be removed by an edge bead removal (EBR) process.

Accordingly, the clumping of the photosensitive resin in the outer area OA may be removed, and the photoresist composition remaining on the side surface of the mask film 120 may be removed. Furthermore, contamination by the photoresist composition on a lower surface of the mask film 120 may be eliminated.

As the outer portion of the photoresist film 130 is removed, an edge portion of the mask film 120 may be exposed.

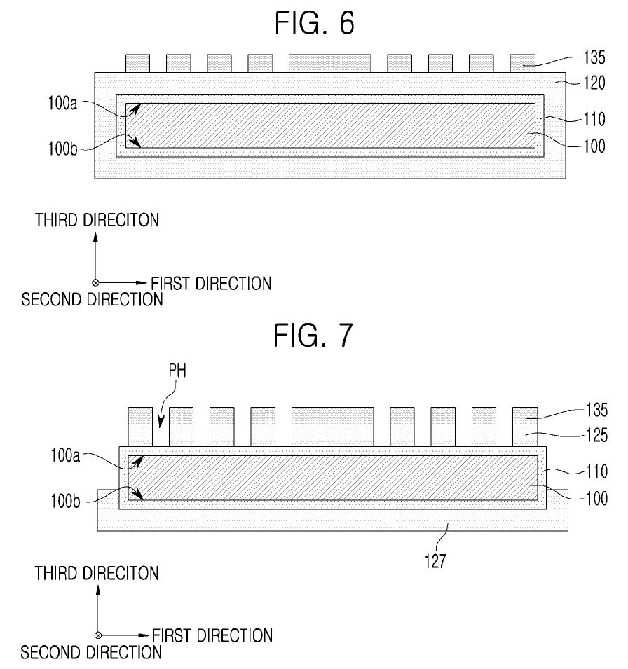

Referring to FIG. 6, the method may include forming a photoresist pattern 135 by partially removing the photoresist film 130.

According to example embodiments, after selectively exposing the photoresist pattern 135, the method may include performing a development process which forms the photoresist pattern 135 through partially removing the photoresist film 130. By the development process, portions of the photoresist film 130 corresponding to the preliminary holes PH or deposition holes DH described later may be removed.

After the development process, a post-baking process for the photoresist pattern 135 may be further performed.

Referring to FIG. 7, the method may include partially removing the mask film 120 by using the photoresist pattern 135 as an etch mask. Accordingly, an upper mask pattern 125 including preliminary holes PH may be formed on the upper surface of the protection film 110.

According to example embodiments, the mask film 120 may be partially removed by a dry etch process using an etch gas having an etch selectivity for silicon nitride. Accordingly, the method may include forming preliminary holes PH by removing a portion of the mask film 120 corresponding to the region of the photoresist film 130 removed through the process described in FIG. 6. Through the preliminary holes PH, the upper surface of the protection film 110 may be exposed.

In some embodiments, the above etching process may partially remove a portion of the mask film 120 formed on the side surface of the protection film 110. Accordingly, the lower mask film 127 may be separated from the mask film 120.

According to example embodiments, the portion of the mask film 120 formed on the lower edge of the mask body 100 or the protection film 110 may be retained by the increased reach of the etch gas. Accordingly, the lower mask film 127 may cover the lower surface (second surface 100b) of the protection film 110 or the mask body 100 and the lower edge together.

Although not illustrated in detail in FIG. 7, the protection film 110 formed on the side surface of the mask body 100 may also be partially removed by the etching process.

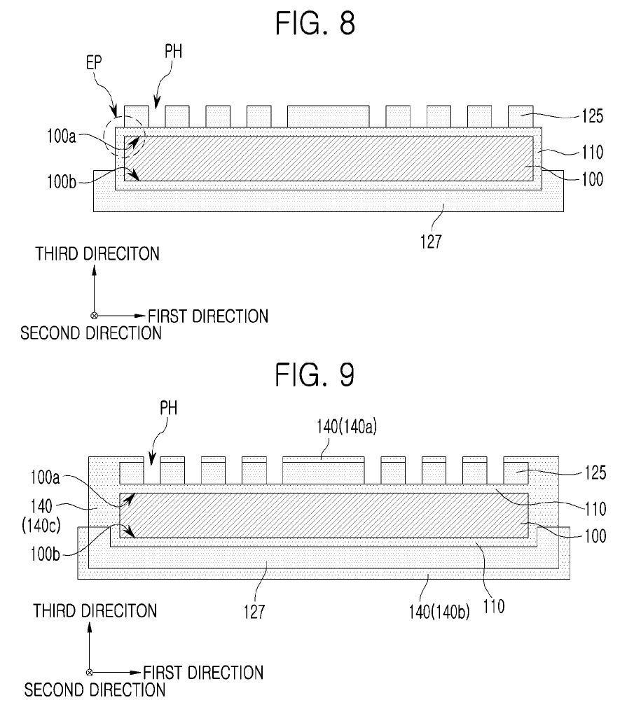

Referring to FIG. 8, the method may include removing the photoresist pattern 135 by an ashing and/or stripping process.

As described herein, the upper mask pattern 125 may include preliminary holes PH, the upper surface of the protection film 110 may be exposed through the preliminary holes PH. In some aspects, the side surface of the protection film 110 may be exposed at an edge region EP (for example, an upper edge) of the mask body 100, indicated by the dashed circle.

Referring to FIG. 9, the method may include forming an additional protection film 140. According to example embodiments, the additional protection film 140 may be formed by a second oxidation process. The second oxidation process may include a thermal oxidation process.

Accordingly, the method may include forming or growing the additional protection film 140 by oxidizing the upper surface and the outer side surface of the upper mask pattern 125, the side surface of the protection film 110, and the side surface and the lower surface of the lower mask film 127. According to example embodiments, the portion of the protection film 110 formed on the side surface of the mask body 100 may be substantially combined with the additional protection film 140.

The additional protection film 140 may include a first portion 140a formed on the upper surface and the outer side surface of the upper mask pattern 125, a second portion 140b formed on the side surface and the lower surface of the lower mask film 127, and a third portion 140c formed on the side surface of the mask body 100. As described herein, the third portion 140c may be integrally combined with the protection film 110.

The additional protection film 140 may include an oxide-based material substantially the same as the protection film 110, such as silicon oxide.

In an embodiment, the additional protection film 140 may be formed by a deposition process, such as a PECVD process, atomic layer deposition (ALD) process, to include silicon oxide.

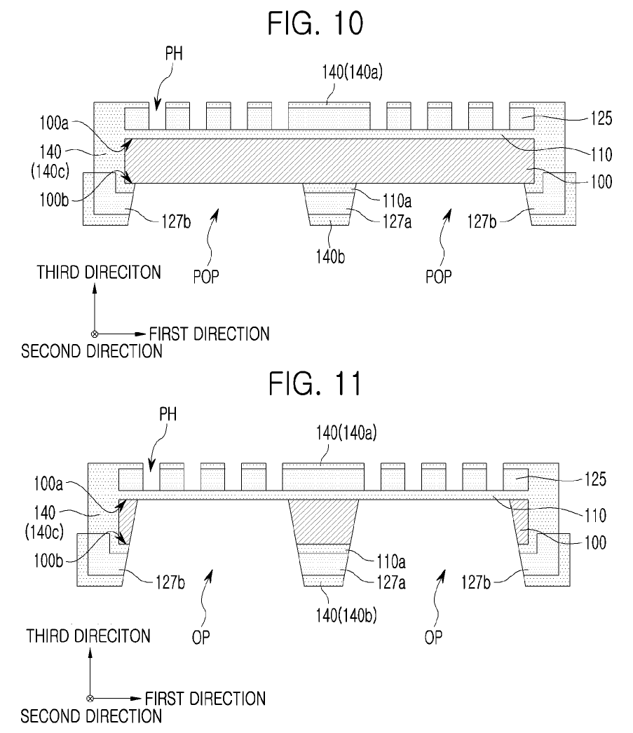

Referring to FIG. 10, the method may include forming a preliminary opening POP by partially removing the layers formed on the second surface 100b of the mask body 100.

According to example embodiments, the second portion 140b of the additional protection film 140, the lower mask film 127, and the protection film 110 may be etched sequentially by a dry etching process. Accordingly, a preliminary opening POP exposing the second surface 100b of the mask body 100 may be formed.

Through the dry etching process, a stacked structure including a first lower protection film pattern 110a formed from the protection film 110, a first lower mask pattern 127a formed from the lower mask film 127, and the second portion 140b of the additional protection film 140 may be formed in an area corresponding to the dummy area DA illustrated in FIG. 2.

On the lower edge of the mask body 100, a second lower mask pattern 127b formed from the lower mask film 127 may remain.

Referring to FIG. 11, the method may include etching the mask body 100 in a direction from the second surface 100b toward the first surface 100aby a back-side etching (BSE) process. Accordingly, the etching may expand the preliminary opening POP and accordingly form an opening OP passing through the mask body 100.

The BSE process may include wet etching, wherein an etchant having an etch selectivity for silicon is used. The etchant may include an alkaline etchant, such as an ammonium hydroxide-based etchant. In an embodiment, the etchant may include a tetramethylammonium hydroxide (TMAH) solution.

According to example embodiments, the plurality of openings OP may be formed to be separated by the stacked structure. Through each of the openings OP, the lower surface of the protection film 110 formed on the first surface 100a of the mask body 100 may be exposed.

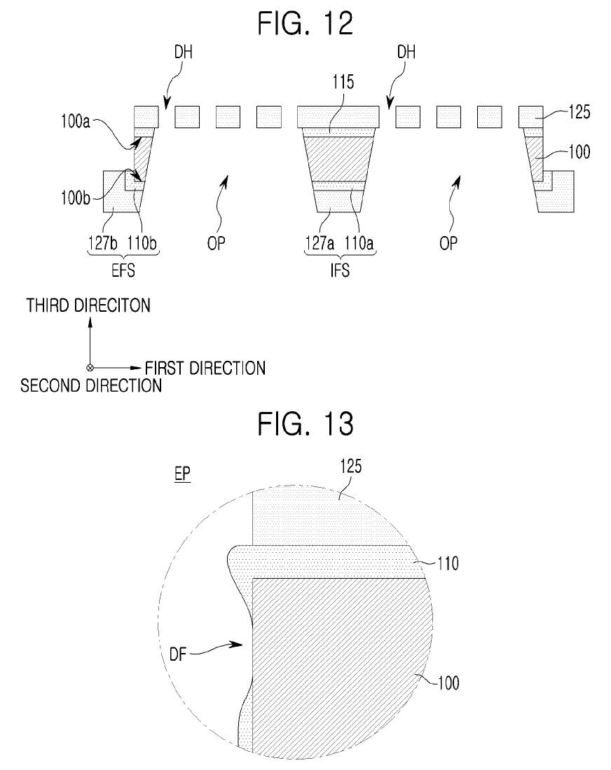

Referring to FIG. 12, the method may include opening or further penetrating the preliminary holes PH and accordingly forming the deposition holes DH.

According to example embodiments, an etchant having an etch selectivity for silicon oxide may be used to etch the portions of the protection film 110 exposed by the preliminary holes PH. Accordingly, deposition holes DH connected to the opening OP may be formed. The upper protection film pattern 115 may be formed from the protection film 110 between the first surface 100a of the mask body 100 and the upper mask pattern 125 in the outer area OA and the dummy area DA.

The etchant may include a buffered oxide etchant (BOE) solution.

The BOE treatment may remove exposed portions of the additional protection film 140 together. For example, the first portion 140aand the second portion 140b of the additional protection film 140 may be removed together by the BOE treatment. In some aspects, the third portion 140c formed on the side surface of the mask body 100 may be removed.

Of the protection film 110, the portion formed on the lower edge of the mask body 100 may be shielded by the second lower mask pattern 127band remain as the second lower protection film pattern 110b.

Accordingly, the edge fence structure EFS including the second lower protection film pattern 110b and the second lower mask pattern 127b may remain on the lower edge of the mask body 100.

On the second surface 100b of the portion of the mask body 100 between neighboring openings OP, the inner fence structure IFS including the first lower protection film pattern 110a and the first lower mask pattern 127a may remain.

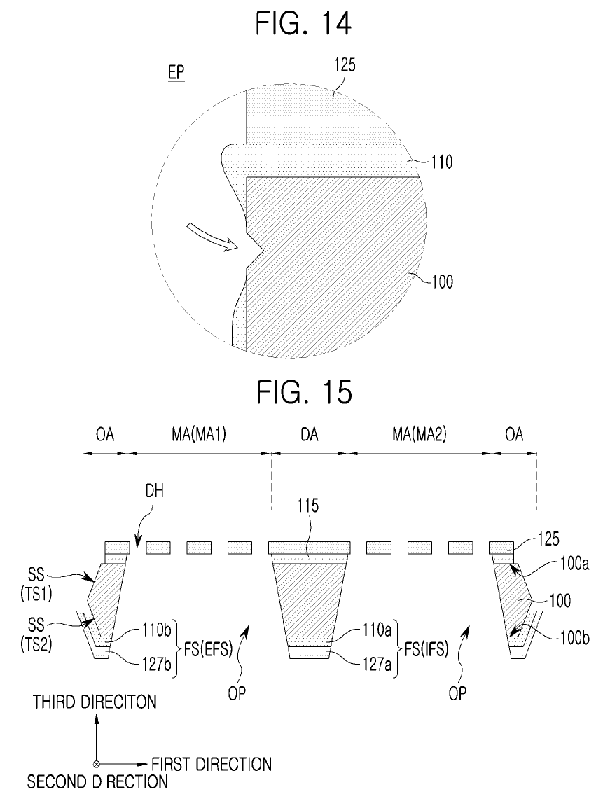

FIG. 13 is a partially enlarged cross-sectional view illustrating a method of manufacturing a deposition mask according to an example embodiment. For example, FIG. 14 is a partially enlarged cross-sectional views illustrating a manufacturing method according to a comparative example in the edge region EP illustrated in FIG. 8.

Referring to FIG. 13, the method may include forming the upper mask pattern 125 by the processes described in FIGS. 3-8 with reference. Although not illustrated in detail in FIGS. 7 and 8, the protection film 110 may also be partially etched or damaged by the dry etching process using the photoresist pattern 135.

Accordingly, as illustrated in FIG. 13, a thinning phenomenon of the protection film 110 may occur on the side surface of the mask body 100, and a defect portion DF in which the side surface of the mask body 100 is exposed may be caused.

Referring to FIG. 14, in a comparative example, if the BSE process of the mask body 100 described with reference to FIG. 11 is performed omitting the formation of the additional protection film 140, the etchant (for example, TMAH solution) may penetrate through the defect portion DF to the side surface of the mask body 100 as indicated by the arrow.

Accordingly, defects such as chipping, cracking, and the like on the side surface of the mask body 100 may be caused.

However, according to embodiments of the present disclosure described herein, prior to the BSE process, the additional protection film 140 may be formed to protect the side surface of the mask body 100. Thus, defect portion DF caused by thinning of the protection film 110 on the side surface of the mask body 100 may be removed and a stable BSE process may be performed.

FIG. 15 is a schematic cross-sectional view illustrating a deposition mask according to example embodiments. A detailed description of substantially the same or similar configurations, structures, and materials as described in FIGS. 1 and 2, which are incorporated by reference, is omitted.

Referring to FIG. 15, a side surface SS of the mask body 100 may include inclined surfaces that face each other. According to example embodiments, the side surface SS of the mask body 100 may include a first inclined surface TS1 and a second inclined surface TS2.

The first inclined surface TS1 may be adjacent to the first surface 100a. The first inclined surface TS1 may be directly connected to the first surface 100a. The second inclined surface TS2 may be adjacent to the second surface 100b. The second inclined surface TS2 may be directly connected to the second surface 100b. The ends of the first inclined surface TS1 and the second inclined surface TS2 may meet each other, and the second inclined surface TS2 may have a curved shape from the first inclined surface TS1.

In the cross-sectional view of FIG. 15, the first inclined surface TS1 may be inclined at an acute angle in a counterclockwise direction with respect to an imaginary plane extending from the first surface 100a. The second inclined surface TS2 may be inclined at an acute angle in a clockwise direction with respect to an imaginary plane extending from the second surface 100b.

As described herein, a fence structure FS may be formed on a lower portion including the second surface 100b of the mask body 100. The fence structure FS may include an inner fence structure FS and an edge fence structure EFS.

The inner fence structure IFS may be formed on the second surface 100b of the mask body 100 between neighboring mask areas MA (for example, a first mask area MA1 and a second mask area MA2).

The edge fence structure EFS may be formed on the second surface 100b of the mask body 100 and the second inclined surface TS2 in the outer area OA. According to example embodiments, the edge fence structure EFS may have a curved structure based on the shape of the second inclined surface TS2. The edge fence structure EFS may not extend over the first inclined surface TS1.

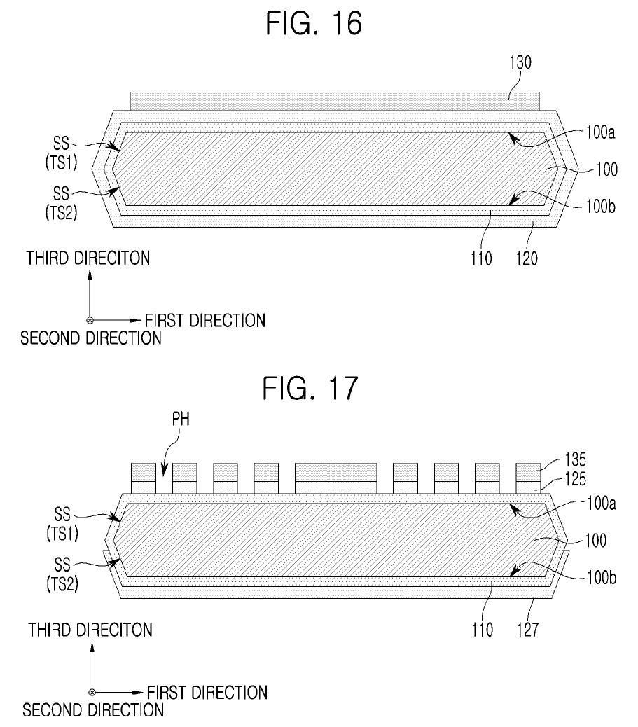

FIGS. 16-20 are schematic cross-sectional views illustrating a method of manufacturing a deposition mask according to example embodiments. A detailed description of the processes, which are substantially the same or similar to the processes described in FIGS. 3-12, which incorporate by reference, is omitted.

Referring to FIG. 16, the method may include preparing a mask body 100 including a side surface SS having first and second inclined surfaces TS1, TS2, for example, from a silicon wafer, as described in FIG. 15 with reference.

Subsequently, substantially the same or similar processes to those described with reference to FIGS. 3-5 may be performed. Accordingly, a protection film 110 and a mask film 120 may be formed sequentially on a surface of the mask body 100. On an upper surface of the mask film 120, a photoresist film 130 may be formed by coating of a photoresist composition and an EBR process.

Referring to FIG. 17, the method may include performing substantially the same or similar processes as the processes described with reference to FIGS. 6 and 7.

Accordingly, the method may include forming a photoresist pattern 135 by partially removing the photoresist film 130 through exposure and development processes. The method may include partially removing the mask film 120 by a dry etching using the photoresist pattern 135 as an etch mask to form the upper mask pattern 125, which includes the preliminary holes PH, and the lower mask film 127.

According to example embodiments, the dry etching may remove a portion of the mask film 120 located on the first inclined surface TS1. At least a portion of the mask film 120 located on the second inclined surface TS2 may be shielded by the first inclined surface TS1 and may be un-etched by the dry etching process. Accordingly, at least some of the portions of the mask film 120 located on the second inclined surface TS2 may remain.

Accordingly, a lower mask film 127 may be formed on the second surface 100b of the mask body 100 and the second inclined surface TS2.

After the dry etching, the photoresist pattern 135 may be removed by an ashing and/or stripping process, as described with reference to FIG. 8.

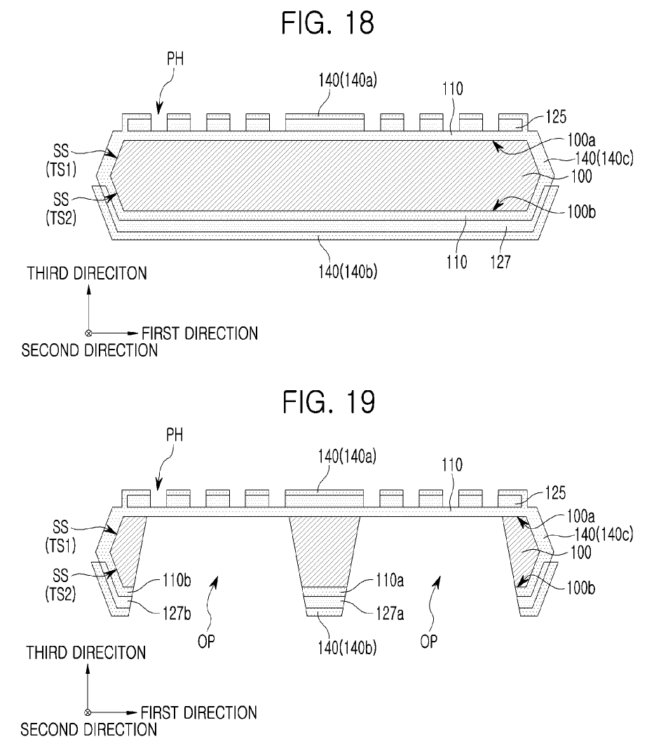

Referring to FIG. 18, the method may include forming an additional protection film 140 by performing a process substantially the same or similar to the process described with reference to FIG. 9.

As described with reference to FIG. 9, the additional protection film 140 may include a first portion 140a formed on an upper surface and an outer side surface of the upper mask pattern 125, a second portion 140b formed on a side surface and a lower surface of the lower mask film 127, and a third portion 140c formed on a side surface SS of the mask body 100. The third portion 140c may be integrally combined with the protection film 110.

Referring to FIG. 19, the method may include performing substantially the same or similar processes as those described with reference to FIGS. 10 and 11.

Accordingly, the method may include forming the preliminary opening POP by partially etching the stacked structure on the second surface 100b of the mask body 100 (see FIG. 10). By the etching, a first lower protection film pattern 110a and a second lower protection film pattern 110b may be formed on the lower portion of the mask body 100 from the protection film 110, and a first lower mask pattern 127a and a second lower mask pattern 127b may be formed from the lower mask film 127.

Thereafter, for example, an opening OP may be formed by expanding the preliminary opening POP by the BSE process, to expose a portion of the protection film 110 formed on the first surface 100a of the mask body 100. As described herein, the side surface of the mask body 100 may be reliably protected by the third portion 140cof the additional protection film 140. Accordingly, damage to the side surface of the mask body 100 by the BSE process may be prevented.

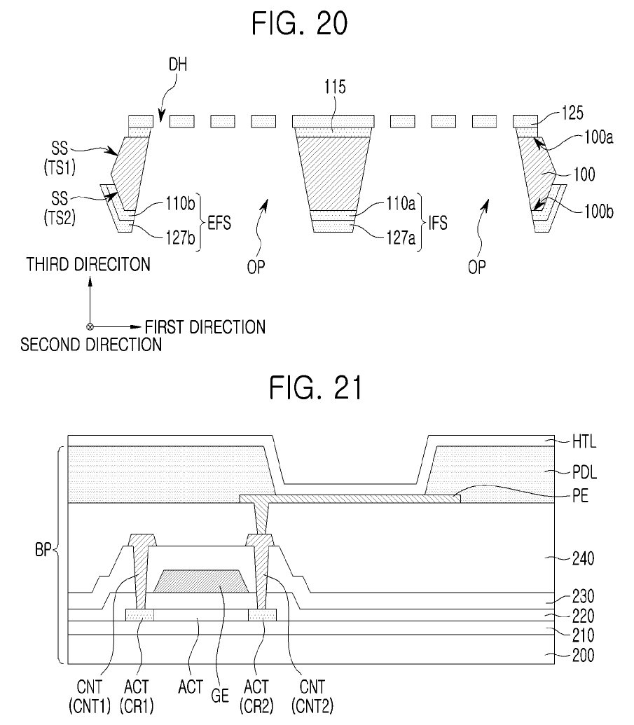

Referring to FIG. 20, the method may include performing a process substantially the same or similar to the process described with reference to FIG. 12.

Accordingly, for example, the method may include performing the BOE treatment to open the preliminary holes PH to form deposition holes DH connected to the openings OP.

The first portion 140a and the second portion 140b of the additional protection film 140 may be removed together by the BOE treatment. Further, the third portion 140c formed on the first inclined surface TS1 of the mask body 100 may be removed.

Of the protection film 110, the portion formed on the lower edge of the mask body 100 may be shielded by the second lower mask pattern 127b and remain as the second lower protection film pattern 110b.

Accordingly, on the lower edge including the second inclined surface TS2 of the mask body 100, the edge fence structure EFS including the second lower protection film pattern 110b and the second lower mask pattern 127b may remain.

On the second surface 100b of the portion of the mask body 100 between the neighboring openings OP, the inner fence structure FS including the first lower protection film pattern 110a and the first lower mask pattern 127a may remain.

The upper protection film pattern 115 may be formed from the protection film 110 between the first surface 100a of the mask body 100 and the mask pattern 125 in the outer area OA and the dummy area DA.

FIGS. 21-25 are schematic drawings illustrating a method of manufacturing a display device according to example embodiments.

Referring to FIG. 21, the method may include manufacturing a backplane structure BP including a base substrate 200 and transistors and pixel electrodes PE formed on the base substrate 200.

The base substrate 200 may be provided as a back-plane substrate of a display device. A glass substrate or a plastic substrate may be used as the base substrate 200. In some embodiments, the base substrate 200 may include a polymeric material having transparency and a predetermined flexibility. In this case, the base substrate 200 may be used in a transparent flexible display device.

For example, the base substrate 200 may include a polymeric material such as polyimide, polysiloxane, epoxy-based resin, acrylic-based resin, or polyester. In an embodiment, the base substrate 200 may include polyimide.

The method may include forming a buffer layer 210 on an upper surface of the base substrate 200. The buffer layer 210 may block moisture from infiltrating through the base substrate 200, and the diffusion of impurities between the base substrate 200 and the structure formed on the base substrate 200 may be blocked. The buffer layer 210 may cover the upper surface of the base substrate 200 entirely.

The buffer layer 210 may include an inorganic insulating material, such as, for example, silicon oxide, silicon nitride, or silicon oxynitride. These may be used alone or in combination of two or more. In some embodiments, the buffer layer 210 may have a stacked structure including a silicon oxide film and a silicon nitride film. The buffer layer 210 may be formed by a deposition process, such as a chemical vapor deposition (CVD) process, a sputtering process, an atomic layer deposition (ALD) process, or the like, to include the inorganic insulating material described herein.

In some embodiments, the buffer layer 210 may include an organic layer and may have a multilayer structure of organic and inorganic layers.

The method may include forming a semiconductor layer on an upper surface of the buffer layer 210 by a deposition process, such as a sputtering process. The semiconductor layer may be patterned to be arranged repeatedly/regularly on each pixel by a photo etch process to form an active layer ACT.

In some embodiments, the semiconductor layer may be formed to include a silicon compound such as polysilicon or amorphous silicon. In some embodiments, the semiconductor layer can be formed to include an oxide semiconductor such as Indium Gallium Zinc Oxide (IGZO), Zinc Tin Oxide (ZTO), or ITZO.

The method may include forming a gate insulating layer 220 that covers the active layer ACT on the buffer layer 210. A gate electrode GE may be formed on the gate insulating layer 220.

The gate insulating layer 220 may be formed using any of the inorganic insulating materials and deposition processes described herein.

After forming a first conductive layer on an upper surface of the gate insulating layer 220 by the deposition process described herein, the method may include forming the gate electrode GE by partially removing the first conductive layer using a photo etch process.

For example, the first conductive layer may include a metal such as Ag, Mg, Al, W, Cu, Ni, Cr, Mo, Ti, Pt, Ta, Nd, Sc, or the like, an alloy thereof, or a nitride thereof. In some embodiments, the first conductive layer may be formed in a multilayer structure (for example, a Ti layer, an Al layer, and a Ti layer).

Subsequently, the method may include implanting a p-type dopant or a n-type dopant into the active layer ACT by an ion implantation process using the gate electrode GE as an ion implantation mask. Accordingly, a first contact region CR1 and a second contact region CR2 may be formed on one side and the other side of the active layer ACT, respectively. The first contact region CR1 and the second contact region CR2 may correspond to a source region and a drain region, respectively.

A portion of the active layer ACT between the first contact region CR1 and the second contact region CR2, which is vertically overlapped with the gate electrode GE, may be defined as a channel region.

A transistor may be defined by the active layer ACT including the channel region, the first contact region CR1, and the second contact region CR2, the gate insulating layer 220, and the gate electrode GE. The transistor may be provided as a thin film transistor (TFT) of the display device, and may be provided as a pixel drive transistor or a switching transistor.

On the active layer ACT, an interlayer insulating layer 230 covering the gate insulating layer 220 and the gate electrode GE may be formed. On the interlayer insulating layer 230, a contact electrode CNT may be formed that is in contact or electrically connected with the active layer ACT.

The interlayer insulating layer 230 may be formed by the deposition process described herein to include an inorganic insulating material such as silicon oxide, silicon nitride, silicon oxynitride, or the like. The interlayer insulating layer 230 may be formed as a monolayer structure or as a multilayer structure including different materials.

In some embodiments, the gate insulating layer 220 may be formed in a pattern covering the channel region by an etch process using the gate electrode GE as an etch mask. If the active layer ACT includes an oxide semiconductor, hydrogen contained in the interlayer insulating layer 230 may diffuse or migrate into the active layer ACT when the interlayer insulating layer 230 is formed. Accordingly, a carrier concentration may be increased by the hydrogen, and contact regions CR1, CR2 may be formed on the side parts of the active layer ACT.

The contact electrode CNT passes through the interlayer insulating layer 230 and may be in contact or connected to the active layer ACT. The contact electrode CNT may also pass through the gate insulating layer 220.

The contact electrode CNT may include a first contact electrode CNT1 that is in contact with or connected to the first contact region CR1 of the active layer ACT and a second contact electrode CNT2 that is in contact with or connected to the second contact region CR2 of the active layer ACT. The first contact electrode CNT1 and the second contact electrode CNT2 may be provided as a source electrode and a drain electrode, respectively.

The method may include forming contact holes by partially etching the interlayer insulating layer 230. For example, contact holes exposing the first contact region CR1 and the second contact region CR2 respectively may be formed. After forming a second conductive layer sufficiently filling the contact holes on the interlayer insulating layer 230, the method may include forming the first contact electrode CNT1 and the second contact electrode CNT2 by partially etching the second conductive layer.

The second conductive layer may include a metal or alloy substantially the same or similar to the first conductive layer, and may be formed by the deposition process described herein, such as a sputtering process.

On the interlayer insulating layer 230, the method may include forming a planarization layer 240 covering the contact electrode CNT. The planarization layer 240 may accommodate via portions that electrically connect the pixel electrode PE and the second contact electrode CNT2.

In some embodiments, the planarization layer 240 may include an organic material such as a polyimide, epoxy-based resin, acrylic-based resin, polyester, siloxane-based resin, benzocyclobutene (BCB), or the like. For example, the planarization layer 240 may be formed by a coating process, such as a spin coating process.

For each pixel, the method may include forming a pixel electrode PE may be formed and electrically connected to the transistor. The pixel electrodes PE may be formed on the planarization layer 240 and electrically connected to, for example, the second contact electrode CNT2.

For example, the method may include partially etching the planarization layer 240 to form via holes that expose the upper surface of the second contact electrode CNT2. The method may include forming a conductive layer including a metallic material or a transparent conductive oxide sufficiently filling the via hole on the upper surface of the planarization layer 240, and then forming a pixel electrode PE by etching the conductive layer. The pixel electrode PE may include the via portion filling the via hole.

The pixel electrode PE may be provided as an anode and may include a high work function conductive material that promotes hole injection. The pixel electrode PE may be provided as a permeable electrode. The pixel electrode PE may include a transparent conductive oxide such as indium tin oxide (ITO), indium zinc oxide (IZO), zinc oxide (ZnO), indium tin zinc oxide (ITZO), and the like.

The pixel electrode PE may be provided as a semi-transmissive electrode or a reflective electrode. The pixel electrode PE may include a metal selected from Ag, Mg, Cu, Al, Pt, Pd, Au, Ni, Nd, Ir, Cr, Li, Ca, LiF, Mo, Ti, W, In, Sn, Zn, or an alloy of two or more of these.

The pixel electrode PE may have a monolayer structure or a multilayer structure. For example, the pixel electrode PE may have a three-layer structure of ITO/Ag/ITO.

On the planarization layer 240, the method may include forming a pixel defining layer PDL that exposes the upper surface of the pixel electrode PE. The pixel defining layer PDL may be formed to at least partially expose the upper surface of the pixel electrode PE, and pixels may be defined. The pixel defining layer PDL may cover a periphery of the pixel electrode PE.

For example, a pixel region or light emitting region may be defined by a sidewall of the pixel defining layer PDL.

The pixel defining layer PDL may include an organic material, such as, for example, a polysiloxane resin, a polyimide resin, an acrylic resin, or the like. The pixel defining layer PDL may also include a color material, such as a black pigment/dye dispersed in the resin material.

In some embodiments, the method may include forming a hole transport layer HTL on the backplane structure BP manufactured as described herein. The hole transport layer HTL may be formed as a common layer formed on a plurality of pixels continuously.

For example, the hole transport layer HTL may include m-MTDATA(4,4',4"-[tris(3-methylphenyl)phenylamino] triphenylamine), TDATA(4,4'4"-tris(N,N-diphenylamino)triphenylamine), 2-TNATA(4,4',4"-tris[N(2-naphthyl)-N-phenylamino]-triphenylamine), NPB(N,N'-di(naphthalene-l-yl)-N,N'-diphenyl-benzidine), TPD (N,N'-bis(3-methylphenyl)-N,N'-diphenyl-[1,1'-biphenyl]-4,4'-diamine), TCTA (4,4',4"-tris(N-carbazolyl)triphenylamine), PEDOT/PSS (poly(3,4-ethylenedioxythiophene)/poly(4-styrenesulfonate)), and the like.

The hole transport layer HTL may be formed by processes such as thermal deposition, vapor deposition, vacuum deposition, spin coating, inkjet printing, laser printing, casting, laser thermal transfer, and the like.

In an embodiment, the method may include further forming a hole injection layer between the pixel electrode PE and the hole transport layer HTL.

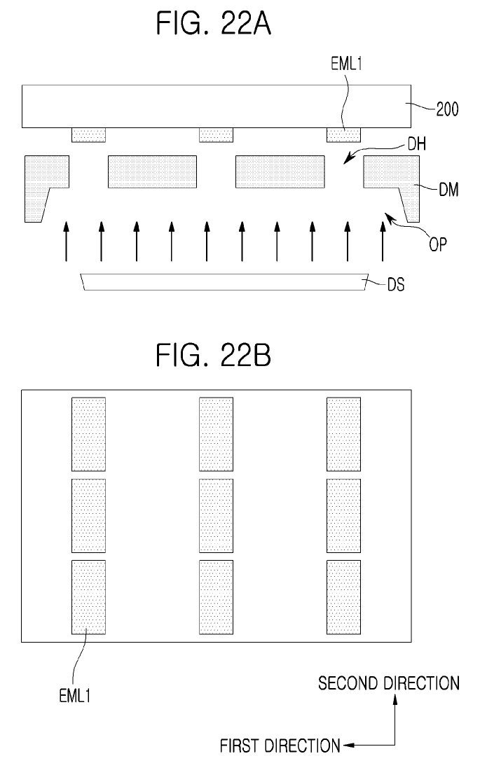

Referring to FIG. 22A and 22B, a backplane structure BP may be disposed on the deposition mask DM according to the above-described embodiments. For ease of illustration, the remaining configurations of the backplane structure BP, other than the base substrate 200, and the hole transport layer HTL are omitted in FIGS. 22A, 22B, 23A, 23B, 24A, and 24B. In some aspects, the drawings of the detailed structure are omitted, except for the deposition holes DH of the deposition mask DM and the openings OP.

According to example embodiments, the backplane structure BP may be aligned such that the pixel electrode PE of the backplane structure BP face the deposition holes DH of the deposition mask DM.

As described herein, the hole transport layer HTL may be formed on the pixel electrodes PE. Accordingly, the backplane structure BP and the deposition mask DM may be aligned with each other such that the pixel electrode PE faces the deposition hole DH of the deposition mask DM across the hole transport layer HTL.

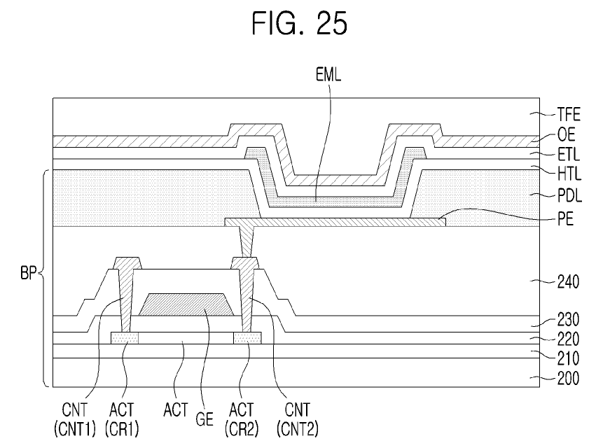

Subsequently, the method may include forming a light emitting layer EML (see FIG. 25) on the pixel electrode PE by a deposition process using the deposition mask DM. In FIGS. 22A and 22B, 23A, 23B, 24A, and 24B,each of FIGS. 22A, 23A, and 24A is a cross-sectional view schematically illustrating the deposition process, and each of FIGS. 22B, 23B, and 24B is a plan view illustrating a form in which the light emitting layer EML is formed.

According to example embodiments, the formation of a first light emitting layer EML1 using a first light emitting material emitting a first color, a second light emitting layer EML2 using a second light emitting material emitting a second color, and a third light emitting layer EML3 using a third light emitting material emitting a third color may be sequentially proceeded by moving the deposition mask DM. The first to third colors may be different colors each other.

As illustrated in FIG. 22A and 22B, the first light emitting material included in the first light emitting layer EML1 may be deposited using the deposition mask DM by the deposition source DS. Accordingly, the first light emitting layers EML1 may be formed on the pixel electrodes PE corresponding to the first pixel, respectively.

According to example embodiments, the organic light emitting material corresponding to the first light emitting material may be supplied from the deposition source DS by thermal evaporation deposition. For example, the organic light emitting material may include a host material that is excited by holes and electrons, and a dopant material that increases the luminescence efficiency through the absorption and release of energy.

The organic light emitting material may be vaporized and injected into the opening OP of the deposition mask DM and sprayed from the deposition holes DH onto the plurality of pixel electrodes PE.

As illustrated in FIG. 22B, the method may include forming a plurality of first light emitting layers EML1 in the second direction to form a row of first light emitting layers. A plurality of rows of first light emitting layers may be formed along the first direction.

In some embodiments, the first light emitting layer EML1 may correspond to a blue light emitting layer.

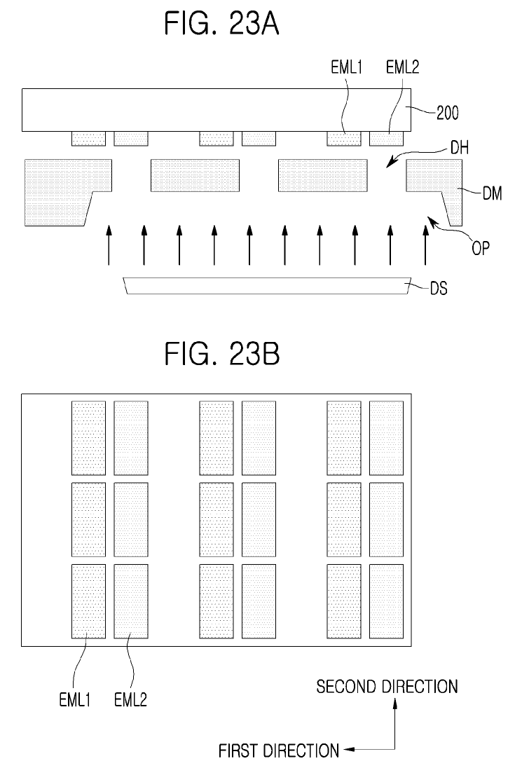

Referring to FIG. 23A and 23B, the deposition mask DM may realign the deposition holes DH to the pixel electrodes PE corresponding to the second pixel.

Subsequently, the second light emitting material included in the second light emitting layer EML2 may be deposited using the deposition mask DM by the deposition source DS.

As illustrated in FIG. 23B, a plurality of second light emitting layers EML2 may be formed in the second direction, such that a row of second light emitting layers may be formed. A plurality of rows of second light emitting layers may be formed along the first direction. For example, the rows of second light emitting layers may be formed between the rows of first light emitting layers.

In some embodiments, the second light emitting layer EML2 may correspond to a red light emitting layer.

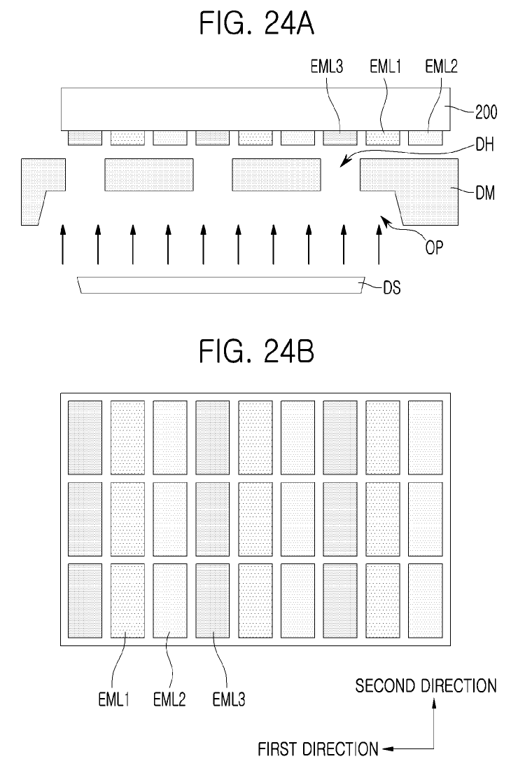

Referring to FIG. 24A and 24B, the deposition mask DM may align the deposition holes DH to the pixel electrodes PE corresponding to the third pixel.

Then, the third light emitting material included in the third light emitting layer EML3 may be deposited using the deposition mask DM by the deposition source DS.

As illustrated in FIG. 24B, the method may include forming a plurality of third light emitting layers EML3 in the second direction to form a row of third light emitting layers. A plurality of rows of third light emitting layers may be formed along the first direction. For example, the third light emitting layer rows may be formed between neighboring the first light emitting layer rows and the second light emitting layer rows.

In some embodiments, the third light emitting layer EML3 may correspond to a green light emitting layer.

Referring to FIG. 25, the method may include forming an electron transport layer ETL on the pixel defining layer PDL (or the hole transport layer HTL) and the light emitting layer EML formed as described in FIGS. 22A, 22B, 23A, 23B, 24A, and 24B with reference. In some embodiments, the electron transport layer ETL may be formed as a common layer continuously provided on the first to third pixels.

The electron transport layer ETL may be an anthracene-based compound, Alq₃(tris(8-hydroxyquinolinato)aluminum), TPBi(1,3,5-Tri(1-phenyl-1H-benzo[d]imidazol-2-yl)benzene), BCP(2,9-dimethyl-4,7-diphenyl-1,10-phenanthroline), Bphen(4,7-diphenyl-1,10-phenanthroline), TAZ(3-(4-biphenylyl)-4-phenyl-5-tert-butylphenyl-1,2,4-triazole), NTAZ(4-(naphthalen-1-yl)-3,5-diphenyl-4H-1,2,4-triazole), tBu-PBD(2-(4-biphenylyl)-5-(4-tert-butylphenyl)-1,3,4-oxadiazole), BAlq (bis(2-methyl-8-quinolinolato-N1,O8)-(1,1'-biphenyl-4-olato)aluminum), and the like.

The electron transport layer ETL may be formed by processes such as thermal deposition, vapor deposition, vacuum deposition, spin coating, inkjet printing, laser printing, casting, laser thermal transfer, and the like.

The method may include forming a counter electrode OE on the pixel defining layer PDL and the light emitting layer EML. The counter electrode OE may be formed on the electron transport layer ETL. In some embodiments, an electron injection layer may be further formed between the counter electrode OE and the electron transport layer ETL.

The counter electrode OE may be formed as a common electrode common to the first to third pixels, provided continuously.

The counter electrode OE may be provided as an electron injection electrode or cathode. The counter electrode OE may include a metal, alloy, electrically conductive compound, or the like having a low work function.

For example, the opposite electrode OE may include lithium (Li), silver (Ag), magnesium (Mg), aluminum (Al), aluminum-lithium (Al-Li), calcium (Ca), magnesium-indium (Mg-In), magnesium-silver (Mg-Ag), ytterbium (Yb), silver-ytterbium (Ag-Yb), ITO, IZO, and the like. They may be used alone or in combination of two or more.

The counter electrode OE may be formed as a transmissive electrode, a semi-transmissive electrode, or a reflective electrode. The counter electrode OE may have a single-layer structure or a multilayer structure.

The method may include forming an encapsulation layer TFE on the counter electrode OE. The encapsulation layer TFE may protect the light emitting layers EML from moisture or oxygen.

The encapsulation layer TFE may be an inorganic film including silicon nitride (SiNₓ), silicon oxide (SiOₓ), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyldisiloxane, acrylic resin (for example, polymethylmethacrylate, polyacrylic acid, or the like), epoxy-based resin (for example, aliphatic glycidyl ether (AGE), or the like), or any combination thereof; or a combination of inorganic and organic films.

The encapsulation layer TFE may be formed in a monolayer or multilayer structure. In some embodiments, the encapsulation layer TFE may have a sequential stacking structure of a first inorganic layer, an organic layer, and a second inorganic layer.

In some embodiments, an optical functional layer or sensor functional layer, such as a color filter, polarizer, touch sensor layer, or the like, may be further formed on the encapsulation layer TFE.

In some example embodiments, high-resolution and fine-pitch light emitting layers EML may be formed using the deposition mask DM manufactured according to the example embodiments. In some embodiments, the display device may be manufactured as a high-resolution organic light emitting diode (OLED) display device, such as virtual reality glasses or augmented reality glasses, such as an OLED on silicon (OLEDoS) display device.

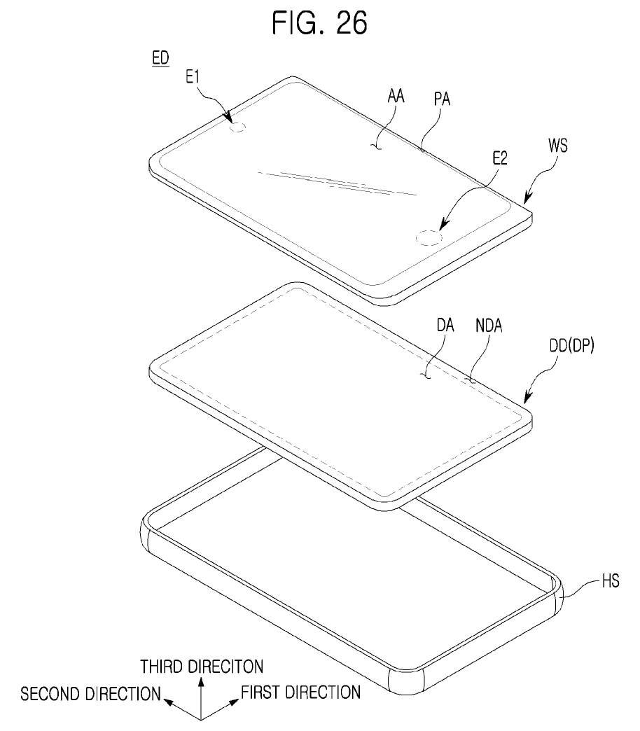

FIG. 26 is an exploded perspective view illustrating an electronic device according to example embodiments.

According to example embodiments, the electronic device ED may be implemented in the form of a mobile phone (smartphone), a tablet, a PC, or the like, including a display device including a light emitting layer formed using the deposition mask DM described herein.

Referring to FIG. 26, the electronic device ED may include a window structure WS, a display device DD, and a housing HS. The display device DD may include a display panel DP including the transistor and the light emitting element described herein. Along the third direction, the housing HS, the display device DD, and the window structure WS may be stacked sequentially.

The window structure WS provides an external display surface that is recognized by a user, such as, for example, a viewing surface of an electronic device such as a mobile phone, and may include a transparent material film. For example, the window structure WS may include glass (for example, ultra-thin glass (UTG)), a hard-coated film, a plastic film, or the like.

The outer surface of the window structure WS may include an active area AA and a peripheral area PA. The active area AA may provide a surface on which an image of the display device DD is substantially displayed and on which a user's touch/command is input. The peripheral area PA may correspond substantially to a bezel area of the electronic device ED.

The display device DD or display panel DP may include a display area DA and a non-display area NDA. The display area DA of the display panel DP may substantially correspond to or overlap the active area AA of the window structure WS. The non-display area NDA of the display panel DP may substantially correspond or overlap with the peripheral area PA of the window structure WS. In some embodiments, the peripheral area PA of the window structure WS may further include a margin area that does not overlap with the non-display area NDA of the display panel DP.

In some embodiments, the active area AA of the window structure WS may include functional element regions E1, E2 in the active area AA. For example, the first functional element region E1 may be included at one end of the active area AA and may be implemented, for example, in the form of a camera hole. The second functional element area E2 may be provided as a fingerprint sensing area.

For example, a sensor structure for touch sensing or fingerprint sensing may be arranged in the display panel DP, or between the window structure WS and the display panel DP.

The housing HS may be provided as a support frame or rear housing for the display device DD or the electronic device ED. A cover panel may be disposed between the housing HS and the display panel DP. The housing HS or the cover panel may include a plate (for example, a SUS plate) supporting the display panel DP. The housing HS or the cover panel may also include an elastic body for shock absorption of the display device DD.

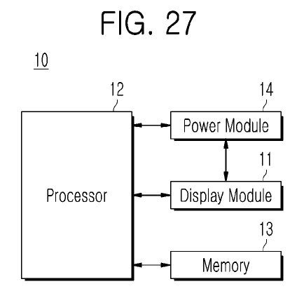

FIG. 27 is a block diagram of an electronic device according to an embodiment.

Referring to FIG. 27, the electronic device 10 according to an embodiment may include a display module 11, a processor 12, a memory 13, and a power module 14.

The processor 12 may include a central processing unit (CPU), an application processor (AP), a graphic processing unit (GPU), a communication processor (CP), an image signal processor (ISP), and/or a controller.

The memory 13 may store data information for operation of the processor 12 or the display module 11. In an example in which the processor 12 executes an application stored in the memory 13, image data signals and/or input control signals are delivered to the display module 11, and the display module 11 may process the received signals to output image information through the display screen.

The power module 14 may include a power supply module, such as a power adapter or a battery unit, and a power conversion module that converts the power supplied by the power supply module to generate the power for operation of the electronic device 10.

At least one of each of the above-described configurations of the electronic device 10 may be included in the display device according to the above-described embodiments. Furthermore, some of the individual modules that are functionally included in one module may be included in the display device and others may be provided separately from the display device. For example, the display module 11 may include the display device, while the processor 12, memory 13, and power module 14 may be provided in the form of other devices in the electronic device 10 other than the display device.

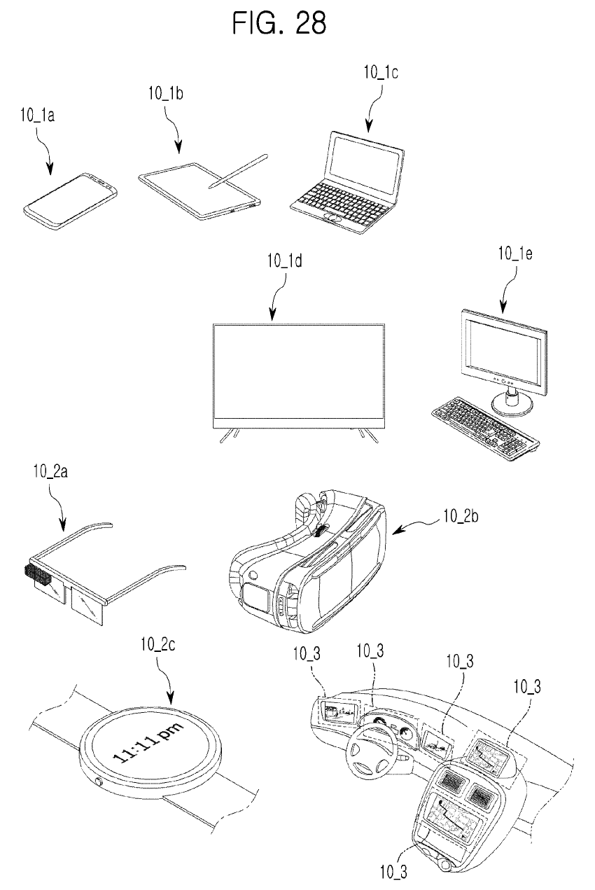

FIG. 28 illustrates schematic drawings of an electronic device according to example embodiments.

Referring to FIG. 28, non-limiting examples of various electronic devices with display devices according to the above-described embodiments include a smartphone 10_1a, a tablet PC 10_1b, a laptop 10_1c, a television 10_1d, a desk monitor 10_1e, and other electronic devices for displaying images; wearable electronic devices including display modules such as smart glasses 10_2a, a head-mounted display 10_2b, a smart watches 10_2c, and the like; and an automotive electronic device 10_3 including a display module such as a center information display (CID) disposed at the instrument cluster, the center fascia, and the dashboard of a vehicle, and a room mirror display. The electronic device may also include virtual reality glasses or augmented reality glasses.

According to embodiments of the present invention, after forming a protection film and a mask pattern on a mask body of a deposition mask, an additional protection film may be formed on the mask body. The additional protection film may protect a side surface of the mask body, thereby preventing damage to the side surface of the mask body during an etching process for forming an opening.

According to example embodiments, the deposition mask may include an edge fence structure, which may improve mechanical stability at the edge part of the deposition source supply surface of the mask body.

What is claimed is:

1. A method of manufacturing a deposition mask comprising:
sequentially forming a protection film and a mask film on surfaces of a mask body, wherein the surfaces comprise a first surface and a second surface opposite each other;
forming, by etching the mask film:
an upper mask pattern comprising preliminary holes on the first surface of the mask body; and
a lower mask film on the second surface of the mask body;
forming an additional protection film on a side surface of the mask body;
forming an opening passing through the mask body by etching the mask body from the second surface; and
forming deposition holes connected to the opening from the preliminary holes by removing a portion of the protection film exposed by the opening.

2. The method according to claim 1, wherein:
the protection film comprises an oxide-based insulating material, and
the mask film comprises a nitride-based insulating material.

3. The method according to claim 2, wherein the additional protection film comprises the oxide-based insulating material.

4. The method according to claim 2, wherein the additional protection film is formed by a thermal oxidation process.

5. The method according to claim 1, wherein:
portions of the additional protection film are formed together on:
an upper surface and an outer side surface of the upper mask pattern, and
a surface of the lower mask film,
the portions of the additional protection film comprise:
a first portion formed on the upper surface and the outer side surface of the upper mask pattern,
a second portion formed on the surface of the lower mask film, and
a third portion formed on the side surface of the mask body, and
the third portion is combined with the protection film on the side surface of the mask body.

6. The method according to claim 5, wherein forming the opening comprises:
forming a preliminary opening by etching the second portion of the additional protection film stacked on the second surface of the mask body, the lower mask film, and the portion of the protection film formed on the second surface of the mask body; and
forming the opening by etching the mask body through the preliminary opening.

7. The method according to claim 6, wherein forming the deposition holes comprises removing the additional protection film.

8. The method according to claim 7, wherein:
removing the additional protection film partially exposes the side surface of the mask body, and
forming the preliminary opening forms a lower mask pattern from the lower mask film, and
forming the preliminary opening forms a lower protection film pattern between the lower mask pattern and the mask body from the protection film.

9. The method according to claim 8, wherein:
the side surface of the mask body comprises:
a first inclined surface adjacent to the first surface, and
a second inclined surface adjacent to the second surface, and
the lower mask pattern and the lower protection film pattern cover the second inclined surface.

10. The method according to claim 7, wherein removing the additional protection film comprises treating the additional protection film with a buffered oxide etchant (BOE) solution.

11. The method according to claim 6, wherein:
the mask body comprises silicon, and
etching the mask body through the preliminary opening comprises wet etching using an alkaline etchant.

12. The method according to claim 1, wherein forming the upper mask pattern and the lower mask film comprises:
forming a photoresist film on an upper surface of the mask film;
removing an outer portion of the photoresist film;
forming a photoresist pattern from a remaining portion of the photoresist film; and
etching the mask film using the photoresist pattern as an etch mask, wherein etching the mask film separates the mask film into the upper mask pattern and the lower mask film.

13. The method according to claim 12, wherein:
etching the mask film partially etches the protection film formed on the side surface of the mask body, and
the additional protection film covers the protection film on the side surface of the mask body.

14. A method of manufacturing a display device comprising:
forming a backplane structure comprising a base substrate, a transistor formed on the base substrate, and pixel electrodes electrically connected to the transistor;
aligning the backplane structure over a deposition mask manufactured according to the method of claim 1 such that the pixel electrodes correspond to each of the deposition holes of the deposition mask;
forming light emitting layers on the pixel electrodes by injecting a light emitting material from the opening of the deposition mask into the deposition holes; and
forming a counter electrode on the light emitting layers.

15. An electronic device comprising:
a display device manufactured according to the method of claim 14;
a memory; and
a processor for executing data contained in the memory to control operation of the display device.

16. The electronic device according to claim 15, wherein the electronic device comprises virtual reality or augmented reality glasses, a smartphone, a tablet PC, a laptop, a television, a desk monitor, smart glasses, a head-mounted display, a smart watch, or an automotive electronic device.

17. A deposition mask comprising:
a mask body comprising:
mask areas,
a dummy area between the mask areas,
an outer area surrounding the mask areas and the dummy area, and
openings respectively overlapping the mask areas;
an upper mask pattern formed on an upper surface of the mask body and comprising deposition holes connected to the openings respectively overlapping the mask areas; and
a fence structure selectively covering a lower surface portion of the dummy area and a lower edge of the outer area of the mask body.

18. The deposition mask according to claim 17, wherein:
the fence structure comprises:
a lower protection film pattern comprising an oxide-based insulating material; and
a lower mask pattern comprising a nitride-based insulating material, and
the lower protection film pattern and the lower mask pattern are stacked sequentially from the lower surface of the mask body.

19. The deposition mask according to claim 17, wherein the fence structure comprises:
an inner fence structure formed on the lower surface portion of the dummy area of the mask body; and
an edge fence structure formed on the lower edge of the outer area of the mask body and partially covering a side surface of the mask body.

20. The deposition mask according to claim 19, wherein:
the side surface of the mask body comprises:
a first inclined surface adjacent the upper surface of the mask body; and
a second inclined surface adjacent the lower surface of the mask body, and
the edge fence structure covers the second inclined surface, but not the first inclined surface.
